(19) United States
(12) Patent Application Publication
(10) Pub. No.: US 2007/0252740 A1
(43) Pub. Date: Nov. 1, 2007

(54) Digital television receiver and method for processing a digital television signal

(75) Inventors: Kyung Mee Lee, Seoul (KR); Chang Sik Yun, Daejeon (KR); Hyung Sun Yum, Incheon (KR)

Correspondence Address: MCKENNA LONG & ALDRIDGE LLP, 1900 K STREET, NW, WASHINGTON, DC, 20006, US

(73) Assignee: LG. Electronics, Inc., Seoul (KR)

(21) Appl. No.: 11/790,888

(22) Filed: Apr. 27, 2007

(30) Foreign Application Priority Data
Apr. 28, 2006 (KR) 10-2006-0039043

(51) Int. Cl. H03M 1/66

(52) U.S. Cl. 341/144

(57) ABSTRACT

A method of processing a digital television signal in a digital television receiver, the method includes receiving a digital television signal including a streaming data table carrying one or more streaming text data representing additional information transmitted a transmitter; parsing the streaming data table, the parsed streaming data table including display time information corresponding to the streaming text data; and displaying the streaming text data in one of virtual channels according to the parsed streaming data table.

This application claims the benefit of Korean Patent Application No. 10-2006-0039043, filed on Apr. 28, 2006, which is hereby incorporated by reference as if fully set forth herein.

### BACKGROUND OF THE INVENTION

1. Field of the Disclosure

The present disclosure relates to a digital television (DTV) receiver and a method for processing the DTV signal.

2. Background

Digital television (DTV) receivers which are currently used in North America and Korea receive channel information from a broadcasting station and provide the channel information to viewers on the basis of the program and system information protocol (PSIP) established in advanced television system committee (ATSC).

The PSIP includes a plurality of tables for specific purposes and each table includes time information, channel number information, and electronic program guide (EPG) information of each channel. Thus, a DTV receiver can use a variety of functions including a reservation recording function using a personal video recorder (PVR) on the basis of the PSIP information.

As DTV receivers come into wide use, interest of users in the DTV receiver increases. Accordingly, requirements of users for a variety of convenient functions are increasing.

Therefore, a transmitter/receiver needs to transmit/receives a variety of additional information as well as broadcast information transmitted basically, such as audio/video.

### SUMMARY

Accordingly, the present disclosure is directed to a digital television (DTV) receiver and a method for processing a DTV signal that substantially obviate one or more problems described above.

For example, the disclosure may disclose a DTV receiver and a method for processing a DTV signal, by which streaming data table may be displayed streaming text data a viewer.

Advantages, objects, and features of the invention in part may become apparent in the description which follows and in part may become apparent to those having ordinary skill in the art upon examination of the following or may be learned from practice of the invention. The objectives and other advantages of the various embodiments of the invention may be realized and attained by the structures and processes described in the written description, in the claims, and in the appended drawings.

To achieve these objects and other advantages and in accordance with the purpose of the invention, as embodied and broadly described herein, a method includes receiving a digital television signal including a streaming data table carrying one or more streaming text data representing additional information transmitted a transmitter; parsing the streaming data table, the parsed streaming data table including display time information corresponding to the streaming text data; and displaying the streaming text data in one of virtual channels.

In another aspect, a digital television receiver includes a tuner arranged to receive a digital television signal; a demodulator arranged to demodulate the digital television signal; a demultiplexer arranged to demultiplex a streaming data table from the demodulated digital television signal including the streaming data table carrying one or more streaming text data representing additional information transmitted from a transmitter; a decoder arranged to parse the streaming data table, the parsed streaming data table including display time information corresponding to the streaming text data; a display unit arranged to display the parsed one or more streaming text data in one of virtual channels according to the parsed streaming data table; and a controller arranged to control operation the decoder and display unit.

It is to be understood that both the foregoing general description and the following detailed description are exemplary and explanatory and should not be construed as limiting the scope of the claims.

### BRIEF DESCRIPTION OF THE DRAWINGS

The accompanying drawings, which are included to provide a further understanding of the disclosure are incorporated in and constitute a part of this application. The drawings together with the description serve to explain the principle of the invention. In the drawings:

FIG. 1 is an exemplary diagram of bit stream syntax for streaming data table (SDT);

FIG. 2 is an exemplary diagram of the structure of a descriptor for defining streaming text data;

FIG. 3A is an exemplary diagram of the structure of a descriptor including streaming text data on weather;

FIG. 3B is an exemplary diagram of defining weather_code in the descriptor shown in FIG. 3A;

FIG. 4A is an exemplary diagram of the structure of a descriptor including streaming text data on stock;

FIG. 4B is an exemplary diagram of defining an indicator in the descriptor shown in FIG. 4A;

FIG. 5 is a block diagram of an exemplary digital television receiver; and

FIG. 6 is an exemplary flowchart of a method for processing a digital television signal including information on streaming text data.

### DETAILED DESCRIPTION

Hereinafter, a digital television (DTV) receiver and a method for processing a DTV signal including streaming text data will be described.

Hereinafter, the term “streaming text data” described herein indicates a variety of additional information necessary for a user, except for broadcast information provided basically, such as audio/video, and is serial encoding data composed of characters or symbols. Accordingly, the DTV receiver must process and provide additional information, such as news or weather information, transmitted to a user in the form of streaming text data.

In general, the streaming text data of the additional information was transmitted/received using an analog vertical blanking interval (VBI) channel. Accordingly, in analog broadcasting, a variety of necessary additional information such as news caption, weather, and stock quotes is transmitted/received by the above-described transmission method.

Hereinafter, the transmission/reception of the streaming text data in digital broadcasting will be described. In the present disclosure, for example, program and system information protocol (PSIP) information will be described.

The PSIP information includes a plurality of tables for specific purposes and each table contains broadcast information, time information, and electronic program guide (EPG) information. Accordingly, when transmitting/receiving the PSIP information including the streaming text data, the streaming text data may be comprised in a predefined table or an additional table for transmitting the streaming text data may be defined. At this time, when the streaming text data is contained in the predefined table, the table should be updated although existing information is not changed.

Hereinafter, in the present disclosure, an example of defining and using a table for the streaming text data when transmitting/receiving the PSIP information comprising the streaming text data will be described. Hereinafter, a table for the streaming text data is called a streaming data table (SDT).

(1) Digital Television Signal Containing Streaming Text Data

Hereinafter, the streaming data table (SDT) including streaming text data will be described. At this time, the streaming text data may be included in the SDT in the form of a descriptor.

The SDT is one of a plurality of tables included in the PSIP information. Accordingly, the SDT may be defined in the same form as the tables in the PSIP information. That is, the SDT includes one or more section. Each section obtained by combining generic data structures is divided into a header including a common form, a message body including actual data recorded according to a purpose of each table section, and a trailer for error checking and correction of the table section. In the SDT, the header comprises a “table_id” field to a “protocol_version” field, the message body comprises a “streaming_text_count” field to a “streaming_text( )”, and the trailer comprises a “CRC_{—}32” field.

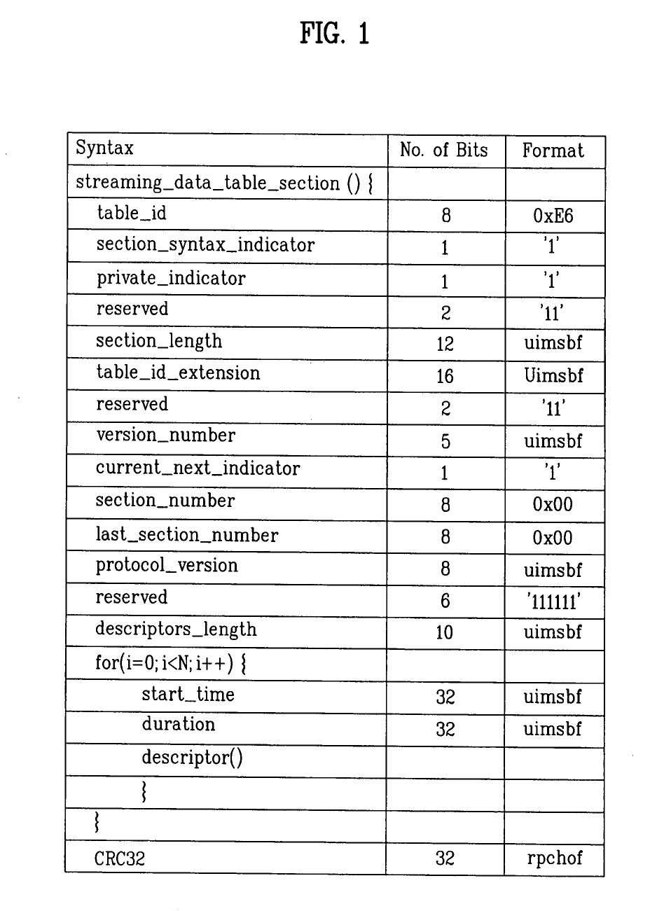

FIG. 1 is an exemplary diagram of bit stream syntax for streaming data table (SDT). Hereinafter, the structure of a SDT section will be described in order of the header to the trailer. For convenience of description, English expressions of fields are used without alteration, but are marked by double quotation marks.

First, the header will be described. A “table_id” is an 8-bit field which should be set to ‘0xE6’, identifying this table as the SDT. A “section_syntax_indicator” is a 1-bit field which should be set to ‘1’. It denotes that the section follows the generic section syntax beyond the section length field. A “private_indicator” is a 1-bit field which should be set to ‘1’. A “section_length” is a 12-bit field specifying the number of remaining bytes in this section immediately following the section_length field up to the end of the section. The value of the section_length field should be no larger than 4093.

A “table_id_extension” is a 16-bit field which should be ‘0x0000’. If the value of the “table_id_extension” field is a specific value, for example, ‘0’, it indicates data which must be processed in one of virtual channels. For example, when a transmitter transmits an urgent important message such as a disaster message in the form of streaming text data, a DTV receiver processes the message in present channel of virtual channels.

A “version_number” is a 5-bit field which is the version number of SDT. The version number should be incremented by 1 modulo 32 when any field in the table_types defined in the loop below or the Streaming Data Table itself changes. The value of this field should be equal to the value of the corresponding entry in a master guide table (MGT). A “current_next_indicator” is a 1-bit indicator which is always set to ‘1’ for the SDT section; the SDT sent is always currently applicable. A “section_number” field is an 8-bit field whose value should be always 0x00 (this table is only one section long). A “last_section_number” is an 8-bit field whose value should be always 0x00. A “protocol_version” is an 8-bit unsigned integer field whose function should be to allow, in the future, this table type to carry parameters that may be structured differently than those defined in the current protocol. At present, the only valid value for protocol_version is zero. Non-zero values of protocol_version may be used by a future version of this standard to indicate structurally different tables.

Next, the message body will be described.

A “descriptor_length” field represents total length (in byte) of the descriptor list containing the streaming text data that follows.

A loop structure includes at least one descriptor containing streaming text data and display time information corresponding to the streaming text data contained in the descriptor.

The streaming text data may be necessary for a user at a specific time, but may be unnecessary for the user after the specific time. Accordingly, the display time information corresponding to the streaming text data may be defined. At this time, the display time information is divided into a display start time of the streaming text data and a duration indicating how long the display continues from the start time. That is, referring to FIG. 1, the start time information of the streaming text data is defined in a “start_time” field and the duration information is defined in a “duration” field.

A “text_start_time” is a 32-bit unsigned integer quantity representing the start time of this streaming text data as the number of global positioning system (GPS) seconds since 00:00:00 UTC, Jan. 6, 1980. A “duration” is a 32-bit field which should be set to seconds. The corresponding descriptor represents an efficient time by seconds. That is, the streaming text data represents the duration after the display start time.

A “descriptor” is a 32-bit field which lists at least one descriptor containing the streaming text data. Each descriptor containing the streaming text data will be described in detail later.

Finally, the trailer will be described. A “CRC_{—}32” is a 32-bit field that contains a cyclic redundancy check (CRC) value that ensures a zero output from the registers in the decoder defined in a moving picture experts group-2 (MPEG-2) system after processing the entire SDT section.

The information of the SDT, such as a packet identifier (PID) or a version, may be defined in the MGT by setting a “table_type” field to ‘0x0006’. Accordingly, when the SDT is contained, the transmitter may contain the information of the SDT in the MGT and the receiver may check whether the SDT is contained by checking the MGT.

In the SDT, the streaming text data is displayed one of virtual channels in a virtual channel table (VCT). Accordingly, a plurality of streaming text data can be individually displayed in one of virtual channels according to the time information (start time and duration of each streaming text data).

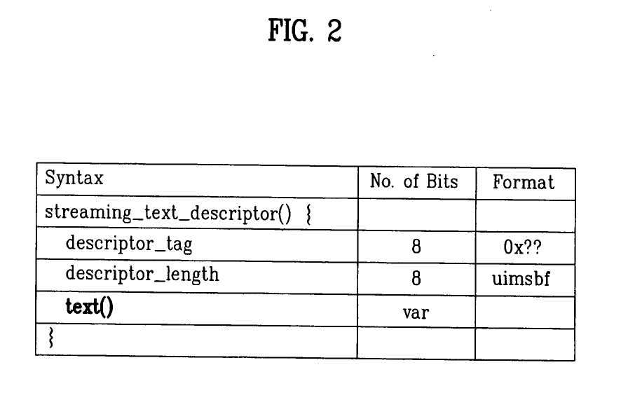

Hereinafter, the descriptors containing the streaming text data will be described. FIGS. 2 to 4B are an exemplary diagram of the descriptors including streaming text data according to the present disclosure.

First, FIG. 2 shows a generic form of the descriptor containing the streaming text data, which will now be described. A “descriptor_tag” is an 8-bit unsigned integer which may have ‘0x??’ which notifies that this descriptor relates to a text. A “descriptor_length” is an 8-bit unsigned integer which may represent the total length (in bytes) of a field next to this field to a last field of this descriptor.

A “text( )” field represents actual streaming text data. As described above, the streaming text data indicates a variety of additional information necessary transmitted from a transmitter, except for broadcast information provided basically, such as audio/video, and is serial encoding data composed of characters or symbols. For example, the streaming text data may contain a variety of additional information such as weather, traffic, and stock. At this time, the text information may be represented in the form of a multiple string structure (MSS) or in the form of a formatted text, such as an extensible markup language/hypertext markup language (XML/HTML).

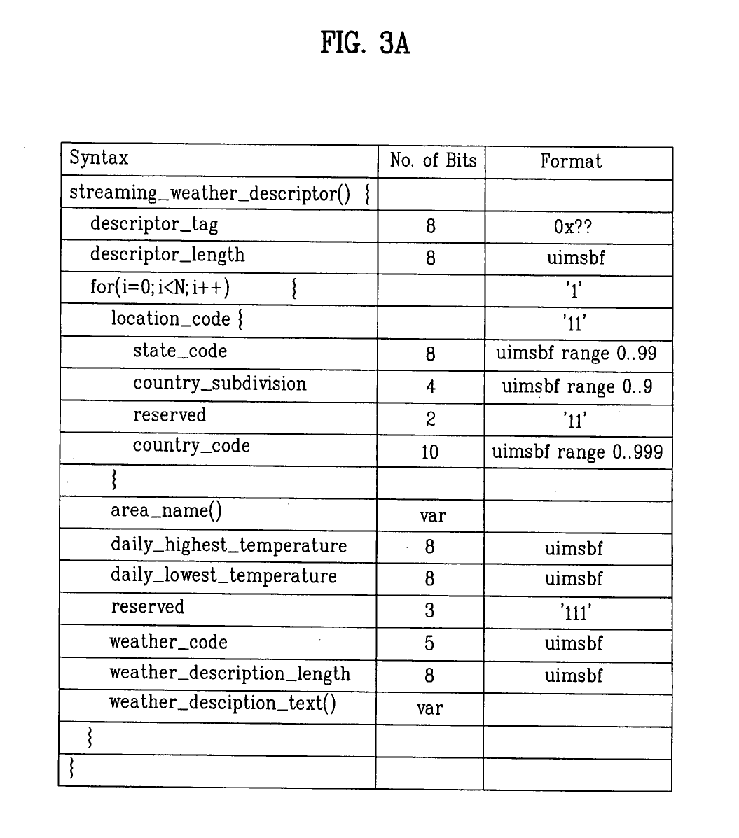

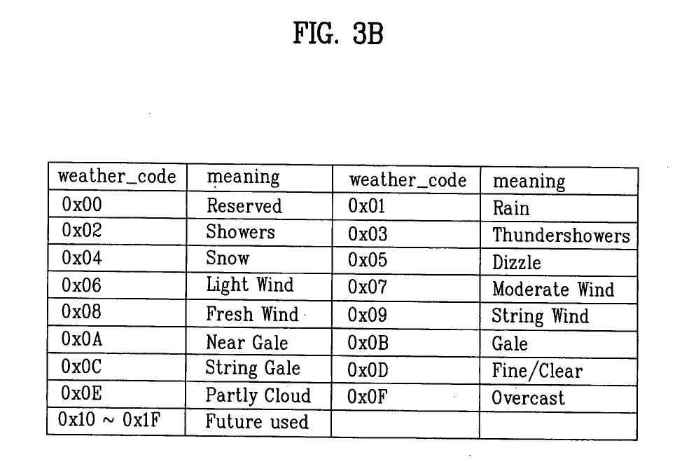

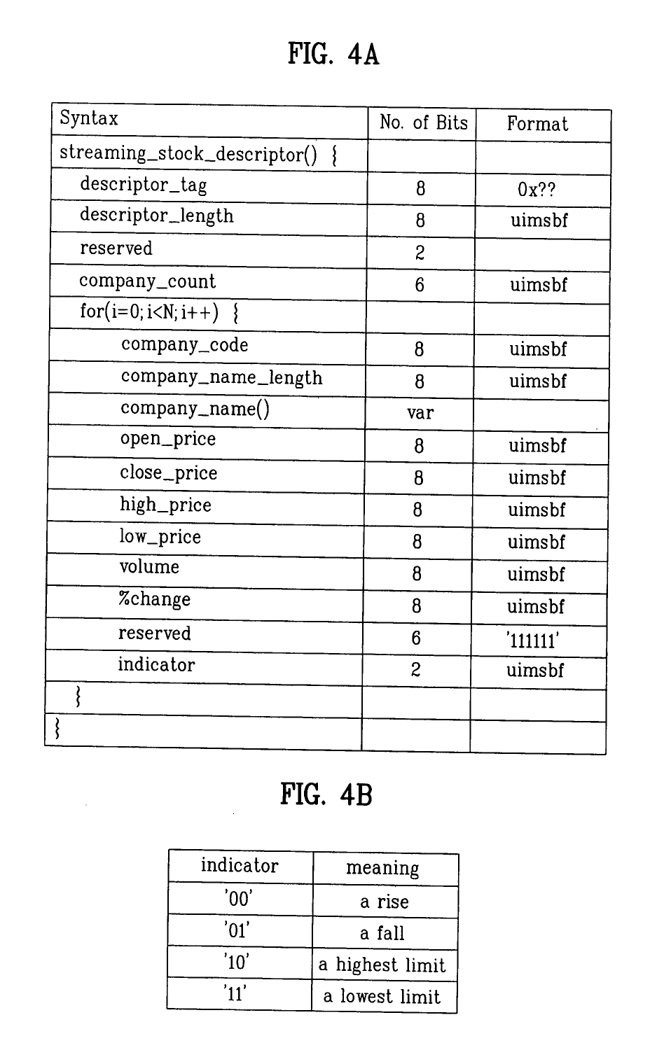

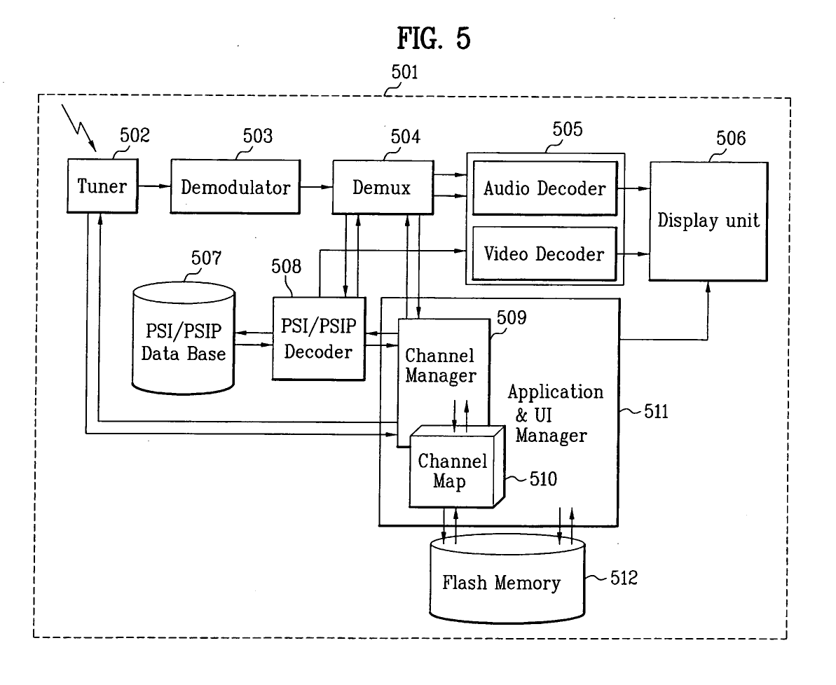

Next, FIGS. 3A to 4B are exemplary diagrams of the text information. Examples of defining the text information in individual descriptors will now be described.

FIG. 3A is an exemplary diagram of a streaming_weather_descriptor which is the descriptor containing weather information as one of the text information. Only a loop structure for indicating actual information will be described.

A “location_code” field also has a loop structure and provides geographical positional information in association with weather information. A “state_code” is an 8-bit field which represents a state code and is an unsigned integer, most significant bit first (uimsbf) in a range of 0 to 99. A “country_subdivision” is a 4-bit field which represents country subdivision and is a unsigned integer, most significant first (uimsbf) in a range of 0 to 9. A “country code” is a 10-bit field which represents a country code and is a uimsbf in a range of 0 to 999.

An “area_name( )” is a variable-bit field which represents an area name. At this time, the “area_name( )” field may be represented by the MSS. A “daily_highest_temperature” is an 8-bit uimsbf which represents a daily highest temperature. A “daily_lowest_temperature” is an 8-bit uimsbf which represents a daily lowest temperature.

A “weather_code” is a 5-bit uimsbf which represents a detailed weather state. In order to represent the detailed weather state, defined weather_codes may be used. FIG. 3B shows an example of defining the weather code. In the weather_code shown in FIG. 3B, it represents rain if the value of the “weather_code” field is ‘0x01’, showers if the value of the “weather_code” field is ‘0x02’, snow if the value of the “weather_code” field is ‘0x04’, light wind if the value of the “weather_code” field is ‘0x06’, near gale if the value of the “weather_code” field is ‘0x0A’, fine/clear if the value of the “weather_code” field is ‘0x0D’, overcast if the value of the “weather_code” field is ‘0x0F’. A “weather_description_length” is an 8-bit uimsbf which represents the length of the below-described “weather_description_text( )” field. A “weather_description_text( )” field represents whole description on weather. At this time, the “weather_description_text( )” field may be represented by the MSS.

FIG. 4A is an exemplary diagram of a streaming_stock descriptor which is the descriptor containing stock information as one of the text information.

A “company_count” is a 6-bit uimsbf which represents the count of at least one company and has a loop structure for detailed information of each company.

A “company_code” field represents a code for identifying the company. A “company_name” field represents the name of the corresponding company. An “open_price” field represents the open price of the corresponding company. A “close_price” field represents the close price of the corresponding company. A “high_price” field represents the high price of the corresponding company. A “low_price” field represents the low price of the corresponding company. A “volume” field represents the volume of stock trading of the corresponding company. A “% change” field represents a change in stock trading of the corresponding company.

An “indicator” field represents detailed information of the change in stock trading. As shown in FIG. 4B, the detailed information represents a rise if the value of the “indicator” is ‘00’, a fall if the value of the “indicator” is ‘01’, a highest limit if the value of the “indicator” is ‘10’, and a lowest limit if the value of the “indicator” is ‘11’.

As described above, even in the digital broadcast, the streaming text data of the additional information can be transmitted/received using the SDT defined as one of the PSIP information for an additional information service. The DTV receiver can selectively display only additional information desired by the user among the plural pieces of descriptor information in the SDT. Since the SDTs are defined according to channels in FIG. 1, one table section per channel is transmitted/received. One channel may contain a descriptor relating to at least one streaming text data displayed in the corresponding channel.

(2) Apparatus for Processing Digital Television Signal

FIG. 5 is a block diagram of a digital television (DTV) receiver for processing a DTV signal including streaming text data.

The DTV receiver 501 includes a tuner 502, a demodulator 503, a demultiplexer 504, an audio/video (A/V) decoder 505, a display unit 506, a program specific information/program and system information protocol (PSI/PSIP) database 507, a PSI/PSIP decoder 508, a channel manager 509, a channel map 510, an application and user interface (UI) manager 511, and a flash memory 512.

The tuner 502 receives and tunes a DTV signal. The tuned DTV signal contains PSIP information. The PSIP information includes a SDT for an additional information service. The operation of the tuner 502 is controlled by the channel manager 509 such that the result of the received DTV signal is recorded in the channel manager 509.

The demodulator 503 receives and demodulates the DTV signal tuned by the tuner 502 into a vestigal side band/enhanced vestigal side band (VSB/EVSB) signal.

The demultiplexer 504 demultiplexes transport packets demodulated by the demodulator 503 into audio, video, and PSI/PSIP information. At this time, the demultiplexing of the PSI/PSIP table information is controlled by the PSI/PSIP decoder 508 and the demultiplexing of the audio and video information is controlled by the channel manager 509.

When the PSI/PSIP decoder 508 sets a packet identifier (PID) for a desired table as a condition, the demultiplexer 504 filters PSI/PSIP table sections for satisfying the PID and transmits the sections to the PSI/PSIP decoder 508. When the channel manager 509 sets an A/V PID of a virtual channel as a condition, the demultiplexer 504 demultiplexes an A/V elementary stream (ES) and transmits the demultiplexed A/V ES to the A/V decoder 505.

The PSI/PSIP decoder 508 parses the PSI/PSIP table demultiplexed by the demultiplexer 504 and reads and records actual section data in the PSI/PSIP database 507.

The channel manager 509 may request the reception of a channel-related information table by referring to the channel map 510 and receive the result. At this time, the PSI/PSIP decoder 508 parses the channel-related information table and transmits a list of A/V PIDs to the channel manager 509. The channel manager 509 may directly control the demultiplexer 504 using the received A/V PIDs to control the A/V decoder 505.

The application and UI manager 511 controls a graphical user interface (GUI) for displaying the reception state of the receiver with an on-screen display (OSD).

In particular, the demultiplexer 504 can filter only the header of the received table sections using the PID, the table identification, the version number, the section number, and the table identification extension. That is, the demultiplexer 504 can parse the header and filter a desired table using the header. For example, the demultiplexer 504 filters only the SDT section for the additional information service among a plurality of tables in the PSIP information.

The PSI/PSIP decoder 508 parses the filtered SDT and obtains and stores the streaming text data in the PSI/PSIP database 507.

The display unit 506 displays the streaming text data stored in the PSI/PSIP database 507 under the control of the application and UI manager 511.

(3) Method for Processing Digital Television Signal

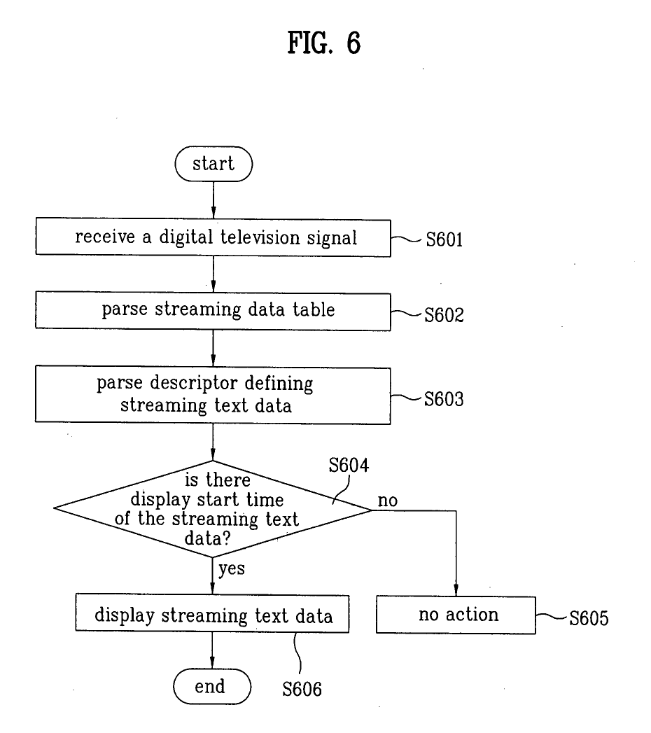

FIG. 6 is an exemplary flowchart of a method for processing a digital television (DTV) signal including the streaming data table (SDT) for the additional information service.

First, The DTV receiver receives a DTV signal including the master guide table (MGT) and SDT. The DTV receiver parses the MGT of a plurality of PSIP information in the received DTV signal. The SDT section is filtered by extracting information as to whether the SDT is contained and the PID of the SDT and controlling the demultiplexer 504 using the extracted PID of the SDT (S601).

The DTV receiver parses the filtered SDT (S602) and parses at least one descriptor for the streaming text data in the SDT (S603).

The DTV receiver determines whether a current time reaches the display start time of the streaming text data using display start time information among a variety of display time information of the streaming text data in the parsed SDT (S604).

The DTV receiver determines that the current time does not reach the display start time, no action is taken (S605). Alternatively, a timer may be set such that the streaming text data is displayed at the start time.

In contrast, the DTV receiver determines that the current time reaches the display start time, the streaming text data is displayed (S606). At this time, the display may use duration information among the variety of time information.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A method of processing a digital television signal in a digital television receiver, the method comprising:
receiving a digital television signal including a streaming data table carrying one or more streaming text data representing additional information transmitted a transmitter;
parsing the streaming data table, the parsed streaming data table including display time information corresponding to the streaming text data; and
displaying the streaming text data in one of virtual channels according to the parsed streaming data table.

2. The method of claim 1, wherein the display time of the streaming text data specifies display start time and duration of the streaming text data.

3. The method of claim 2, wherein the display start time of the streaming text data are in global positioning system (GPS) second.

4. The method of claim 2, wherein the duration of the streaming text data are in seconds.

5. The method of claim 1, wherein the streaming text data has any one of format of multiple string structure (MSS), multilingual text string (MTS) or extensible markup language/hypertext markup language (XML/HTML).

6. The method of claim 1 further comprising determining whether the start time of each streaming text data is passed.

7. The method of claim 6 further comprising setting the timer to display on the start time of each streaming text data.

8. The method of claim 6 further comprising determining whether the duration of each streaming text data is passed.

9. The method of claim 1 further comprising parsing a master guide table, the parsed master guide table defining a type, packet identifiers, and versions for all the other program and system information protocol in transport stream, except for a system time table.

10. The method of claim 9 further comprising determining whether there is the streaming data table according to packet identifier of the streaming data table.

11. The method of claim 1, wherein the streaming text data is represented serial encoding data composed of characters or symbols.

12. A digital television receiver, comprising:
a tuner arranged to receive a digital television signal;
a demodulator arranged to demodulate the digital television signal;
a demultiplexer arranged to demultiplex a streaming data table from the demodulated digital television signal including the streaming data table carrying one or more streaming text data representing additional information transmitted from a transmitter;
a decoder arranged to parse the streaming data table, the parsed streaming data table including display time information corresponding to the streaming text data;
a display unit arranged to display the parsed one or more streaming text data in one of virtual channels according to the parsed streaming data table; and
a controller arranged to control operation the decoder and display unit.

13. The receiver of claim 12, wherein the controller extracts a display start time and duration of each streaming text data.

14. The receiver of claim 13, wherein the controller determines whether the display start time of each streaming text data is passed.

15. The receiver of claim 14, wherein the controller controls the decoder to set timer for displaying each streaming text data on time if the display start time of each streaming text data is not passed.

16. The receiver of claim 14, wherein the controller determines whether the duration of each streaming text data is passed.
